(19) United States
(12) Patent Application Publication
(10) Pub. No.: US 2018/0308685 A1
(43) Pub. Date: Oct. 25, 2018

(54) LOW TEMPERATURE SELECTIVE EPITAXIAL SILICON DEPOSITION

(71) Applicant: Applied Materials, Inc., Santa Clara, CA (US)

(72) Inventors: Geetika BAJAJ, New Delhi (IN); Prerna Sonthalia GORADIA, Mumbai (IN); Robert Jan VISSER, Menlo Park, CA (US)

(21) Appl. No.: 15/951,051

(22) Filed: Apr. 11, 2018

Related U.S. Application Data
(60) Provisional application No. 62/488,360, filed on Apr. 21, 2017.

(51) Int. Cl. H01L 21/02; C23C 16/24; C23C 16/455; C30B 25/02; C30B 29/06

(52) U.S. Cl. CPC H01L 21/0262; H01L 21/02532; C23C 16/24; H01L 21/02381; C30B 25/02; C30B 29/06; C23C 16/45553

(57) ABSTRACT

Implementations described herein generally relate to processes for the fabrication of semiconductor devices in which a self-assembled monolayer (“SAM”) is used to achieve selective epitaxial deposition. In one implementation, a method of processing a substrate is provided. The method comprises exposing a substrate to a self-assembled monolayer (“SAM”) forming molecule to selectively deposit a SAM film on an exposed dielectric material, wherein the substrate comprises the exposed dielectric material and an exposed silicon material. The SAM forming molecule is a chlorosilane molecule. The method further comprises epitaxially and selectively depositing a silicon-containing material layer on the exposed silicon material at a temperature of 400 degrees Celsius or lower. The method further comprises removing the SAM film from the exposed dielectric material.

### CROSS-REFERENCE TO RELATED APPLICATIONS

This application claims benefit of U.S. Provisional Patent Application Ser. No. 62/488,360, filed Apr. 21, 2017, which is incorporated herein by reference in its entirety.

### BACKGROUND

### Field

Implementations described herein generally relate to processes for the fabrication of semiconductor devices in which a self-assembled monolayer (“SAM”) is used to achieve selective epitaxial deposition.

### Description of the Related Art

Reliably producing sub-half micron and smaller features is one of the key technology challenges for next generation very-large-scale integration (VLSI) and ultra-large-scale integration (ULSI) of semiconductor devices. However, as the limits of circuit technology are pushed, the shrinking dimensions of VLSI and ULSI technology have placed additional demands on processing capabilities. Reliable formation of gate structures on substrates is a component of VLSI and ULSI success and to the continued effort to increase circuit density.

As circuit densities increase for next generation devices, the widths of interconnects, such as vias, trenches, contacts, gate structures and other features, as well as the dielectric materials therebetween, decrease to 45 nm and 32 nm dimensions and beyond. In order to enable the fabrication of next generation devices and structures, three-dimensional (3D) stacking of features in semiconductor chips is often utilized. In particular, fin field-effect transistors (FinFETs) are often utilized to form three-dimensional (3D) structures in semiconductor chips. By arranging transistors in three dimensions instead of conventional two dimensions, multiple transistors may be placed close to each other in the integrated circuits (ICs). As circuit densities and stacking increase, the ability to selectively deposit subsequent materials on previously deposited materials gains importance. Selective deposition of subsequent materials at lower temperature is also desirable.

Thus, there is a need for improved methods for selective deposition suitable for three-dimensional (3D) stacking of semiconductor chips or other semiconductor devices that can be performed at lower temperatures.

### SUMMARY

Implementations described herein generally relate to processes for the fabrication of semiconductor devices in which a self-assembled monolayer (“SAM”) is used to achieve selective epitaxial deposition. In one implementation, a method of processing a substrate is provided. The method comprises exposing a substrate to a self-assembled monolayer (“SAM”) forming molecule to selectively deposit a SAM film on an exposed dielectric material, wherein the substrate comprises the exposed dielectric material and an exposed silicon material. The SAM forming molecule is a chlorosilane molecule. The method further comprises epitaxially and selectively depositing a silicon-containing material layer on the exposed silicon material at a temperature of 400 degrees Celsius or lower. The method further comprises removing the SAM film from the exposed dielectric material.

In another implementation, a method of processing a substrate is provided. The method comprises exposing a substrate having an exposed dielectric material and an exposed silicon material to a pre-clean process. The method further comprises exposing the substrate to a self-assembled monolayer (“SAM”) forming molecule to selectively deposit a SAM film on the exposed dielectric material. The SAM forming molecule is a chlorosilane molecule. The method further comprises epitaxially and selectively depositing a silicon-containing material layer on the exposed silicon material at a temperature of 400 degrees Celsius or lower. The method further comprises removing the SAM film from the exposed dielectric material.

In yet another implementation, a method of processing a substrate is provided. The method comprises exposing a substrate having an exposed dielectric material and an exposed silicon material to a plasma pre-clean process performed in a processing chamber. The method further comprises exposing the substrate to a gaseous self-assembled monolayer (“SAM”) forming molecule to selectively deposit a SAM film on the exposed dielectric material in the processing chamber. The SAM forming molecule is a chlorosilane molecule. The method further comprises epitaxially selectively depositing a silicon-containing material layer on the exposed silicon material at a temperature of 400 degrees Celsius or lower in the processing chamber. The method further comprises removing the SAM film from the exposed dielectric material.

### BRIEF DESCRIPTION OF THE DRAWINGS

So that the manner in which the above-recited features of the present disclosure can be understood in detail, a more particular description of the implementations, briefly summarized above, may be had by reference to implementations, some of which are illustrated in the appended drawings. It is to be noted, however, that the appended drawings illustrate only typical implementations of this disclosure and are therefore not to be considered limiting of its scope, for the disclosure may admit to other equally effective implementations.

FIG. 1 is a process flow diagram illustrating one method of selective deposition with self-assembled monolayer films according to implementations described herein; and

FIGS. 2A-2G depict cross-sectional schematic views of a workpiece processed according to implementations described herein.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

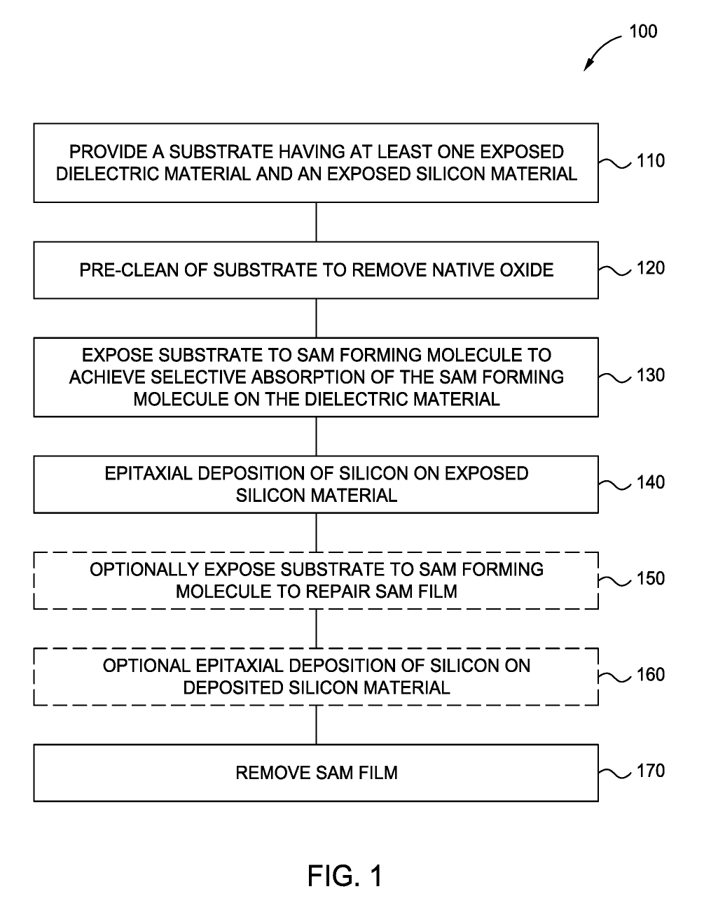

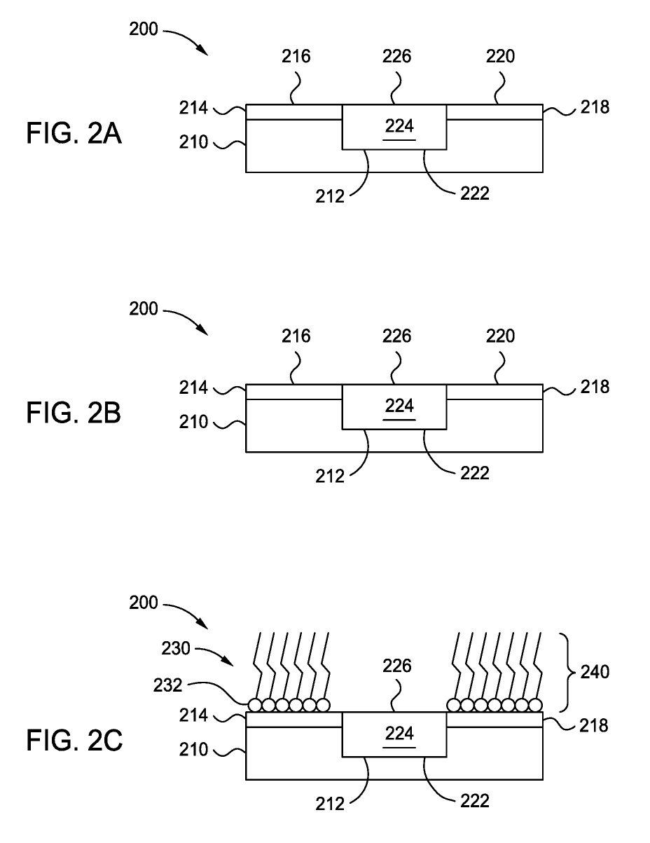

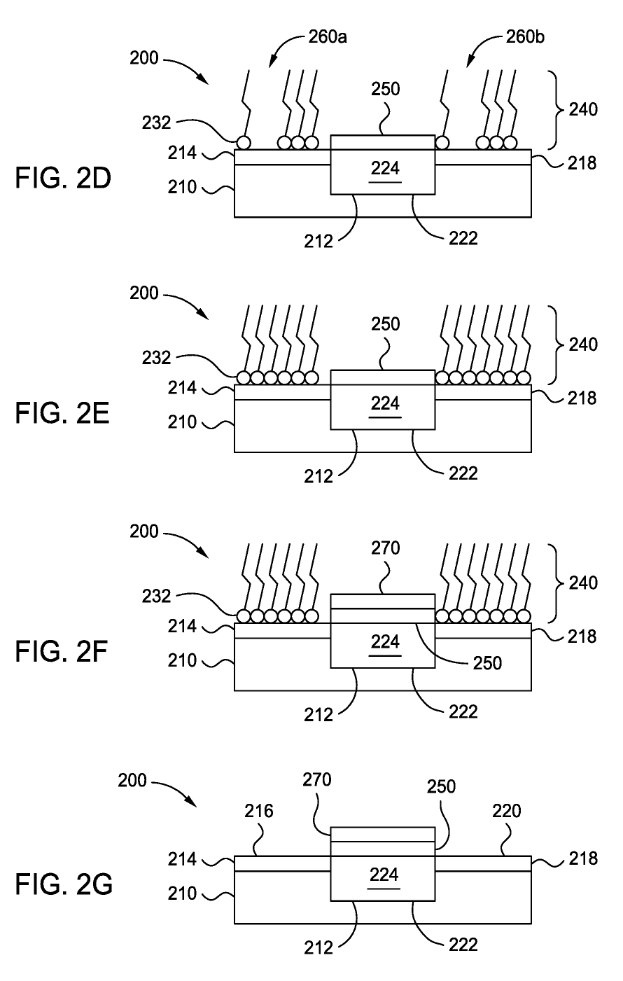

The following disclosure describes processes for the fabrication of semiconductor devices in which a self-assembled monolayer is used to achieve selective deposition at lower temperatures. Certain details are set forth in the following description and in FIGS. 1-2G to provide a thorough understanding of various implementations of the disclosure. Other details describing well-known structures and systems often associated with semiconductor devices, self-assembled monolayers, epitaxial deposition and surface preparation are not set forth in the following disclosure to avoid unnecessarily obscuring the description of the various implementations.

Many of the details, dimensions, angles and other features shown in the Figures are merely illustrative of particular implementations. Accordingly, other implementations can have other details, components, dimensions, angles and features without departing from the spirit or scope of the present disclosure. In addition, further implementations of the disclosure can be practiced without several of the details described below.

Implementations described herein will be described below in reference to cleaning and deposition processes that can be carried out using systems available from Applied Materials, Inc. of Santa Clara, Calif. Other tools capable of performing these cleaning and deposition processes may be adapted to benefit from the implementations described herein. In addition, any system enabling the cleaning and deposition processes described herein can be used to advantage. The apparatus description described herein is illustrative and should not be construed or interpreted as limiting the scope of the implementations described herein.

Current epitaxial silicon deposition-etch processes are highly selective processes performed at high temperatures where silicon grows only on silicon surfaces and not on dielectric surfaces. In practice, both deposition and etch chemistry flow together during these deposition-etch processes. These deposition-etch processes has a balance of deposition and etch chemistry where a small amount of HCl is typically flown with deposition chemistry to etch silicon. This deposition-etch process is highly selective and silicon is typically not deposited on dielectric materials during the process.

Attempts have been made to enable epitaxial silicon deposition processes at lower temperatures due to multiple fabrication requirements. Available techniques enable low temperature deposition processes for epitaxial silicon but the deposition process is no longer selective despite adding HCl as an etchant. The low temperature epitaxial silicon deposition process leads to growth of epitaxial silicon on top of the silicon as well as dielectric materials such as silicon nitride (SiN) and silicon oxide (SiO).

Some implementations of the present disclosure prevent deposition of epitaxial silicon on dielectric materials using a blocking chemistry and imparting selectivity to the low temperature epitaxial growth process.

In some implementations of the present disclosure, substrates were pre-cleaned followed by deposition of the chosen blocking molecule to from a protective SAM on the exposed SiO and exposed SiN surfaces. For this application, the choice of molecule chosen was chlorosilane, which is highly reactive and binds readily on SiO and SiN. Not to be bound by theory but it is believed that chlorosilanes impart SiO and SiN surface hydrophobicity, which helps to prevent nucleation and growth on dielectric surfaces. In some implementations, octadecyltrichlorosilane (ODTS) was used as the blocking molecule. These blocking molecules can be deposited in either liquid phase or vapor phase under suitable process conditions. The liquid phase SAM deposition can be performed using a suitable solvent for the blocking molecule.

In some implementations of the present disclosure, substrates having exposed silicon, silicon oxide and silicon nitride were exposed to 1% HF for sixty seconds to remove native oxides from the surface of the substrate. Then, the cleaned substrate was dipped in ODTS solution in toluene for formation of a SAM on the exposed silicon oxide and silicon nitride and exposed silicon oxide and not on the exposed silicon.

“Self-assembled monolayer” (“SAM”) generally refers to a layer of molecules that are attached (e.g., by a chemical bond) to a surface and that have adopted a preferred orientation with respect to that surface and even with respect to each other. The SAM typically comprises an organized layer of amphiphilic molecules in which one end of the molecule, the “head group” shows a specific, reversible affinity for a substrate. Selection of the head group will depend on the application of the SAM, with the type of SAM compounds based on the substrate utilized. Generally, the head group is connected to an alkyl chain in which a tail or “terminal end” can be functionalized, for example, to vary wetting and interfacial properties. Self-assembled monolayers have been shown, with sufficient time, to cover surfaces so completely that the properties of that surface are changed. The molecules that form the SAM will selectively attach to one material over another material (e.g., silicon vs. dielectric) and if of sufficient density, can successfully block subsequent deposition allowing for selective deposition on materials not coated with the SAM. The molecules that form the SAM film spontaneously align their long chains to form a dense crystalline-like monolayer on the surface.

FIG. 1 is a flow chart depicting a process flow diagram illustrating one method 100 of a selective deposition process performed with SAM films according to implementations described herein. The method 100 is performed upon a workpiece 200 during the fabrication process. The method 100 may be used to form a structure as depicted in the sequence of fabrication stages depicted in FIGS. 2A-2G, which are discussed below. FIGS. 2A-2G depict cross-sectional schematic views of the fabrication of a structure formed on a substrate. Although FIG. 1 is described with reference to the specific structure of FIGS. 2A-2G, it should be understood that reference to the specific structure is only illustrative and the processes described in FIG. 1 are applicable to any process where improved selective deposition of a film on a substrate containing multiple materials is desirable.

At operation 110, a substrate having at least an exposed first material and an exposed second material is provided. The substrate may be similar to substrate 210 depicted in FIGS. 2A-2G. In one implementation, the substrate 210 may comprise a material such as crystalline silicon (e.g., Si<100> or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, and combinations thereof. The substrate 210 may have various dimensions, such as 200 mm, 300 mm, and 450 mm or other diameter, as well as, being a rectangular or square panel. Unless otherwise noted, implementations and examples described herein are conducted on substrates with a 200 mm diameter, a 300 mm diameter, or a 450 mm diameter substrate. In the implementation depicted herein, the substrate 210 may be a crystalline silicon substrate. Moreover, the substrate 210 is not limited to any particular size or shape. The substrate 210 may be a round substrate having a 200 mm diameter, a 300 mm diameter or other diameters, such as 450 mm, among others. The substrate 210 may also be any polygonal, square, rectangular, curved or otherwise non-circular workpiece, such as a polygonal glass substrate used in the fabrication of flat panel displays.

The substrate 210 may include a feature 212. The feature 212 may include, for example, trenches, vias, holes, openings, lines, the like, and combinations thereof. A first material layer 214 (e.g., a dielectric material) having an exposed surface 216 is formed on a surface of the substrate 210. A second material layer 218 (e.g., a dielectric material) having an exposed surface 220 is also formed on the surface of the substrate 210. In one implementation, the feature 212 has an opening 222 that is filled with a third material 224 (e.g., a silicon material) having an exposed surface 226 disposed on the substrate 210 as shown in FIG. 2A. It should be understood that the first material layer 214 and the second material layer 218 may both be dielectric materials. In some implementations, the first material layer 214 is a silicon oxide layer and the second material layer 218 is a silicon nitride layer. In some implementations, the first material layer 214 and the second material layer are formed from the same dielectric material (e.g., both silicon nitride or silicon oxide). In some implementations, the feature 212 is not present and the exposed surface 226 is the surface of the substrate 210.

At operation 120, the workpiece 200 is exposed to a pre-clean process prior to the SAM film formation process of operation 130. The pre-clean process may be any pre-clean process capable of removing native oxides, contaminants, or both from the exposed surfaces. The pre-clean process may be a dry chemical clean process, a wet chemical clean process, or both. The pre-clean process may be a remote plasma clean or an in-situ plasma clean that is adapted to perform a dry etch process. One exemplary dry cleaning process is the SICONI™ Pre-clean process available from Applied Materials, Inc., which removes native oxide through a low-temperature, two-part dry chemical clean process using NF₃ and NH₃. The pre-clean process may be an ex-situ pre-clean process or an in-situ pre-clean process (e.g., without exposure to atmosphere in between cleaning and additional processing of the substrate).

In one implementation, operation 120 includes exposing the workpiece 200 to an ex-situ organic wet clean. In one implementation, the ex-situ organic wet clean process is a sonication process in the presence of an organic liquid. In one implementation, the ex-situ organic wet clean includes at least one of sonication in acetone, sonication in IPA, and sonication in water. In one implementation, the ex-situ organic wet clean includes a ten-minute sonication in acetone, followed by a ten-minute sonication in IPA, followed by a ten-minute sonication in water.

In one implementation, operation 120 includes exposing the workpiece 200 to a hydrofluoric acid (HF) solution. The hydrofluoric acid solution may be in liquid or vapor phase. The hydrofluoric acid solution may be a dilute hydrofluoric (DHF) acid solution. The hydrofluoric acid may be buffered, buffered hydrofluoric acid (BHF), or non-buffered. Exemplary buffering agents for buffering HF include ammonium fluoride (NH₄F). The hydrofluoric acid solution is chosen because it is believed that the hydrofluoric acid solution will remove native oxides from the surface of the workpiece 200. Factors such as the concentration of the dilute hydrofluoric acid solution and the time-period of exposure of the workpiece 200 to the dilute HF will affect the amount of native oxides removed from the surface of the workpiece 200.

The workpiece 200 may be dipped in the dilute acid solution for a period of, for example, about 30 seconds to about 800 seconds. In some implementations, the dilute acid solution may be sprayed onto the workpiece 200. Optionally, following exposure of the workpiece 200 to the hydrofluoric acid solution, a post-exposure rinse process using, for example, DI water, may be used to clean the substrate surface. The optional clean process may be followed by an optional drying process using drying methods known in the art.

The hydrofluoric acid solution may be a dilute solution of hydrofluoric acid (HF) in deionized water. The hydrofluoric acid solution may be from about 0.1% by volume to about 100% by volume hydrofluoric acid. The hydrofluoric acid solution may be from about 1% by volume to about 70% by volume hydrofluoric acid. The hydrofluoric acid solution may include hydrofluoric acid at a concentration of about 0.1% by volume to about 5% by volume, for example, about 0.5% by volume to about 1% by volume. The hydrofluoric acid dip may be performed at room temperature (e.g., about 20 degrees Celsius). The dipping time may vary depending upon the hydrofluoric acid concentration and the amount of native oxide present on the surface of the workpiece 200.

In one implementation, the workpiece 200 undergoes an ex-situ wet organic clean with a ten minute sonication in acetone, followed by ten minute sonication in IPA, followed by ten minute sonication in water. The workpiece 200 is then dipped into a beaker, which contains a 2% HF/water solution with a layer of toluene on top for 2 minutes. After 2 minutes, the sample is pulled out through the layer of toluene and quickly transferred into an ODTS solution before the layer of toluene evaporates from the surface of the workpiece 200.

At operation 130, the substrate 210 is exposed to a SAM forming molecule to achieve selective adsorption of the SAM forming molecule on the exposed surface 216 of the first material layer 214 and the exposed surface 220 of the second material layer 218 with minimal to no adsorption on the exposed surface 226 of the third material 224 as shown in FIG. 2C. Depending upon the materials used and the SAM forming molecules used, the SAM forming molecule may be a solution based precursor or a gaseous precursor. The substrate 210 may be exposed to the SAM forming molecule in a vapor deposition process (e.g., a chemical vapor deposition (CVD) process) or a dip-coating process, where the substrate 210 is dipped into a solution containing the SAM forming molecule. The SAM forming molecule may comprise SAM forming molecules 230, precursors that form the SAM forming molecules 230, or both. The adsorbed SAM forming molecules 230 form a SAM film 240.

The SAM film 240 comprises an organized layer of the SAM forming molecules 230, which may be amphiphilic, in which one end of the molecule, the head group 232 shows a specific, reversible affinity for the first material layer 214 and the second material layer 218 of the feature 212. The head group 232 is typically connected to an alkyl chain in which a terminal end “R” 234 can be functionalized. The SAM film 240 is formed by chemisorption of the head group 232 onto the first material layer 214 and the second material layer 218 of the feature 212, followed by two-dimensional organization of the hydrophobic tail groups. SAM adsorption can occur from solution by immersion of the substrate 210 into a dilute solution containing the SAM forming molecules. In one implementation, the SAM film 240 is deposited via spin coating from a solution. SAM adsorption can also occur from vapor deposition by exposing the substrate 210 to a gaseous precursor. The adsorbed molecules initially form a disordered mass of molecules and then begin to form crystalline or semi-crystalline structures on the first material layer 214 and the second material layer 218 of the workpiece 200. The thickness of the SAM film 240 can be adjusted by adjusting the carbon chain length of the alkyl chain of the SAM forming molecules 230. Generally, the SAM film 240 may only be formed on the surface that has chemical reaction capability with the SAM forming molecules 230.

In the implementation depicted in FIG. 2C, the SAM precursor utilized to form the SAM film 240 is selected to only chemically react with the exposed surface 216 of the first material layer 214, (e.g., a silicon oxide material) and the exposed surface 220 of the second material layer 218, rather than the exposed surface 226 of the third material 224 (e.g., a silicon material). By doing so, the SAM film 240 may be predominantly formed on the exposed surface 216 of the first material layer 214 and the exposed surface 220 of the second material, leaving the exposed surface 226 of the third material 224 free of the SAM film 240.

In one implementation, the SAM film 240 is formed at a pressure from about 50 millitorr to about 10 Torr (e.g., from about 50 mTorr to 1 Torr; from about 50 millitorr to about 500 millitorr; from about 1 Torr to about 10 Torr; or from about 5 Torr to about 10 Torr). In one implementations, the SAM film 240 is formed for a time period between about 50 milliseconds to about 10 minutes (e.g., from about 50 milliseconds to about 200 milliseconds; from about 50 milliseconds to about 100 milliseconds; from about 1 minute to about 5 minutes; or from about 5 minutes to about 10 minutes).

In another implementation, the SAM forming molecules may be chlorosilane molecules, such as methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane (ODTS), nonadecyltrichlorosilane, and combinations thereof.

At operation 140, a low temperature deposition process, which is a process highly sensitive to surface conditions, having selected precursors, is then performed to form a structure 250 selectively on the exposed surface 226 of the third material 224, as shown in FIG. 2D. In one implementation, the structure 250 is formed from a silicon-containing material. In one implementation, the structure 250 is formed from polycrystalline silicon.

The structure 250 may be formed by various deposition techniques including, for example, CVD such as plasma-enhanced CVD (PE-CVD), pulsed-CVD, low pressure CVD (LPCVD), epitaxial growth, atomic layer deposition (ALD), hot-wire CVD (HWCVD), hydride vapor phase epitaxial (HVPE) processes, atomic layer deposition (ALD) processes, Atomic Layer Epitaxy (ALE) and/or any other suitable process. In one implementation, the deposition process of operation 140 is a CVD process, for example, a Hot-Wire CVD (HWCVD) process. The deposition technique is typically a low temperature deposition process. The low temperature deposition process is typically performed at a temperature of 600 degrees or less (e.g., between 300 degrees Celsius and 600 degrees Celsius; between 500 degrees Celsius and 600 degrees Celsius; between 300 degrees Celsius and 500 degrees Celsius; between 300 degrees Celsius and 400 degrees Celsius; between 100 degrees Celsius and 600 degrees Celsius or between 100 degrees Celsius and 400 degrees Celsius). The material selected to be deposited may be influenced by the surface properties of the substrate. The thickness of the structure 250 will vary depending on the materials and particular device being formed. The SAM film 240 prevents deposition of the material of the structure 250 on the exposed surface 216 of the first material layer 214 and the exposed surface 220 of the second material layer 218. In this manner, a selective deposition process may selectively deposit different materials at different locations on the substrate.

In one implementation, the silicon-containing material is formed from a processing gas. The processing gas may include at least one of a silicon-containing precursor gas, a boron-containing precursor gas, a hydrogen-based precursor gas, and inert gases. Exemplary silicon-containing precursor gases for forming the structure 250 include silane-containing precursor gases, including, but not limited to silane (SiH₄), disilane (Si₂H₆), higher order silanes, and the like. Exemplary boron-based precursor gases for forming the structure 250 include, but are not limited to, trimethylboron ((B(CH₃)₃) or TMB), diborane (B₂H₆), boron trifluoride (BF₃), and triethylboron ((B(C₂H₅)₃) or TEB) and combinations thereof. Suitable hydrogen-based precursor gases include, but are not limited to, H₂, H₂O, H₂O₂ and combinations thereof.

In one implementation, the deposition process is an ALD process. As the ALD process is sensitive to surface conditions, ALD is suitable for a selective deposition of materials on specific regions of the substrate. The ALD process is a CVD process with self-terminating/limiting growth. The ALD process yields a thickness of only a few angstroms or in a monolayer level. The ALD process is controlled by distribution of a chemical reaction into two separate half reactions, which are repeated in cycles. The thickness of the material formed by the ALD process depends on the number of the reaction cycles. The first reaction provides a first atomic layer of molecular layer being absorbed on the substrate and the second reaction provides a second atomic layer of molecular layer being absorbed on the first atomic layer. As such, the ordered structure of the material acts as a template for the growth of the material layer.

As shown in FIG. 2D, in some implementations, after deposition of the structure 250, the SAM film 240 may be damaged. This damage may take the form of holes or pinholes 260a, 260b (collectively 260) that expose portions of at least one of the exposed surface 216 and the exposed surface 220. During subsequent deposition processes, these exposed or unprotected portions may have materials deposited thereon. Thus, in some implementations, the substrate 210 is exposed to a repair process at operation 150.

At operation 150, the workpiece 200 may be exposed to a SAM film repair process to repair damage to the SAM film 240 that occurs during the epitaxial deposition process of operation 140. This damage may include pinholes present in the SAM film 240 after formation of the structure 250 during operation 140 as shown in FIG. 2D. The repair process of operation 150, may include repeating the SAM film formation process of operation 130. In one implementation, the repair process of operation 150 may include at least one of the following: chemical treatment of the SAM to block pinholes via steric hindrance, plasma treatment of the SAM to form a blocking layer on the SAM, exposing the SAM to a chemical precursor to form a blocking layer on the SAM, or combinations thereof. In one implementation, repair of the pinholes may include repeating the process of operation 130.

In one implementation, the repair process of operation 150 includes exposing the deposited SAM film 240 to a plasma treatment process. Not to be bound by theory but it is believed that the plasma treatment process densifies the deposited SAM film 240 reducing the number of pinholes formed during the deposition process of operation 130. Depending on the type of deposition and plasma pinhole reduction techniques used, one or more of the power sources connected to the substrate can be a DC source, a pulsed DC (pDC) source, an RF source, a pulsed RF source, etc. Similarly, one or more of the target power sources can be a DC source, a pDC source, an RF source, a pulsed RF source, etc. The post-deposition treatment involves inducing a maintaining a plasma over the workpiece 200 to provide ion bombardment of the deposited SAM film 240 for restructuring the surface morphology of the SAM film 240 and in some implementations compositional modification of the SAM film 240 itself.

In one implementation, the SAM film 240 is densified by exposing the workpiece 200 to an RF plasma. Essentially no additional material is deposited on the SAM film 240, but the impact of the accelerated ionic species serves to densify the SAM film 240.

At operation 160, the deposition process of operation 140 may be repeated to selectively deposit additional material 270 on the structure 250.

At operation 170, following the deposition processes of operations 140, 150 and 160, the SAM film 240 is removed from the exposed surface 216 of the first material layer 214 and the exposed surface 220 of the second material layer 218 as shown in FIG. 2G. The SAM film 240 may be removed by any process, which does not adversely affect the structure 250 or the exposed surface 216 and the exposed surface 220. The process for removing the SAM film 240 is the result of the selection of the terminal and head groups of the SAM forming molecules. The SAM film 240 may be removed by a wet etching process, a dry etching process, a low temperature anneal process (e.g., less than 150 degrees Celsius) to release the SAM film 240 from the exposed surface 216 of the first material layer 214 and the exposed surface 220 of the second material layer 218.

In summary, some benefits of some implementations of the present disclosure provide methods for achieving selective epitaxial deposition at temperatures of 400 degrees Celsius or less. This ability to perform epitaxial deposition at lower temperatures improves the available temperature-processing window allowing for fabrication of multiple devices. In some implementations, this selective epitaxial deposition is achieved via use of a blocking material, which deposits on dielectric materials (e.g., silicon oxide, silicon nitride, or both) while leaving silicon surfaces exposed. The blocking material may be deposited in the same chamber as the subsequently deposited epitaxial layer, which reduces the formation of unwanted oxides on the exposed silicon material.

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the present disclosure may be devised without departing from the basic scope thereof, and the scope thereof is determined by the claims that follow.

1. A method of processing a substrate, comprising:
exposing a substrate to a self-assembled monolayer (“SAM”) forming molecule to selectively deposit a SAM film on an exposed dielectric material, wherein the substrate comprises the exposed dielectric material and an exposed silicon material, wherein the SAM forming molecule is a chlorosilane molecule;
epitaxially and selectively depositing a silicon-containing material layer on the exposed silicon material at a temperature of 400 degrees Celsius or lower; and
removing the SAM film from the exposed dielectric material.

2. The method of claim 1, wherein the SAM film has one or more pinholes formed therein after epitaxially and selectively depositing the silicon-containing material layer on the exposed silicon material.

3. The method of claim 2, further comprising exposing the substrate to the SAM forming molecule to repair the one or more pinholes.

4. The method of claim 1, further comprising epitaxially and selectively depositing additional silicon-containing material on the silicon-containing material layer on the exposed silicon material at the temperature of 400 degrees Celsius or lower prior to removing the SAM film.

5. The method of claim 1, wherein the chlorosilane molecule is selected from the group consisting of: methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane (ODTS), nonadecyltrichlorosilane, and combinations thereof.

6. The method of claim 1, wherein exposing the substrate to the SAM forming molecule comprises exposing the substrate to a solution containing the SAM forming molecule.

7. The method of claim 1, wherein exposing the substrate to the SAM forming molecule comprises exposing the substrate to a gaseous SAM forming molecule.

8. The method of claim 1, wherein exposing the substrate to the SAM forming molecule to selectively deposit the SAM film and epitaxially and selectively depositing the silicon-containing material layer on the exposed silicon material are performed in the same processing chamber.

9. A method of processing a substrate, comprising:
exposing a substrate having an exposed dielectric material and an exposed silicon material to a pre-clean process;
exposing the substrate to a self-assembled monolayer (“SAM”) forming molecule to selectively deposit a SAM film on the exposed dielectric material, wherein the SAM forming molecule is a chlorosilane molecule;
epitaxially and selectively depositing a silicon-containing material layer on the exposed silicon material at a temperature of 400 degrees Celsius or lower; and
removing the SAM film from the exposed dielectric material.

10. The method of claim 9, wherein the pre-clean process comprises a plasma clean process using NF₃ and NH₃.

11. The method of claim 9, wherein the pre-clean process comprises exposing the substrate to an ex-situ organic wet clean.

12. The method of claim 9, wherein the pre-clean process comprises exposing the substrate to a hydrofluoric acid (HF) solution.

13. The method of claim 9, wherein the chlorosilane molecule is selected from the group consisting of: methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane (ODTS), nonadecyltrichlorosilane, and combinations thereof.

14. The method of claim 9, wherein exposing the substrate to the SAM forming molecule comprises exposing the substrate to a solution containing the SAM forming molecule.

15. The method of claim 9, wherein exposing the substrate to the SAM forming molecule comprises exposing the substrate to a gaseous SAM forming molecule.

16. The method of claim 9, wherein exposing the substrate to the SAM forming molecule to selectively deposit the SAM film and the epitaxially and selectively depositing the silicon-containing material layer on the exposed silicon material are performed in the same processing chamber.

17. A method of processing a substrate, comprising:
exposing a substrate having an exposed dielectric material and an exposed silicon material to a plasma pre-clean process performed in a processing chamber;
exposing the substrate to a gaseous self-assembled monolayer (“SAM”) forming molecule to selectively deposit a SAM film on the exposed dielectric material in the processing chamber, wherein the SAM forming molecule is a chlorosilane molecule;
epitaxially and selectively depositing a silicon-containing material layer on the exposed silicon material at a temperature of 400 degrees Celsius or lower in the processing chamber; and
removing the SAM film from the exposed dielectric material.

18. The method of claim 17, wherein the plasma pre-clean process comprises a plasma clean process using NF₃ and NH₃.

19. The method of claim 17, wherein the chlorosilane molecule is selected from the group consisting of: methyltrichlorosilane, ethyltrichlorosilane, propyltrichlorosilane, butyltrichlorosilane, pentyltrichlorosilane, hexyltrichlorosilane, heptyltrichlorosilane, octyltrichlorosilane, nonyltrichlorosilane, decyltrichlorosilane, undecyltrichlorosilane, dodecyltrichlorosilane, tridecyltrichlorosilane, tetradecyltrichlorosilane, pentadecyltrichlorosilane, hexadecyltrichlorosilane, heptadecyltrichlorosilane, octadecyltrichlorosilane (ODTS), nonadecyltrichlorosilane, and combinations thereof.

20. The method of claim 17, wherein the SAM film has one or more pinholes formed therein after the epitaxially selectively depositing the silicon-containing material layer on the exposed silicon material.
